(19) United States
(12) Patent Application Publication
(10) Pub. No.: US 2026/0197003 A1
(43) Pub. Date: Jul. 9, 2026

(54) DYNAMIC LEVEL VOLTAGE SHIFTER CIRCUIT FOR INTEGRATED CIRCUITS

(71) Applicant: NVIDIA Corporation, Santa Clara, CA (US)

(72) Inventors: Lalit Gupta, Freemont, CA (US); Cagri Erbagci, Pittsburgh, PA (US)

(21) Appl. No.: 19/009,385

(22) Filed: Jan. 3, 2025

(51) Int. Cl. H03K 19/0185; G11C 11/412; G11C 11/419; H03K 3/356; H10B 10/00

(52) U.S. Cl. CPC H03K 19/018521; G11C 11/412; G11C 11/419; H03K 3/356113; H10B 10/12

(57) ABSTRACT

Dynamic voltage level shifter circuit including first, second and third set of series-connected transistors. The first set connected to an input power at a first voltage, an input data signal at a second voltage and a clock signal at the first voltage. The second set connected to the input power at the first voltage, a complement of the input data signal at a second voltage and the clock signal at the first voltage. The third set cross-connected to receive a level shifted output signal at a low short circuit current at the first voltage from the first set of series-connected transistors and cross-connected to receive a level shifted complement of the output data signal at the low short circuit current at the first voltage from the second set of series-connected transistors. Integrated circuit including the dynamic voltage level shifter circuit.

### TECHNICAL FIELD

This application is directed, in general, to voltage level shifter circuits and more specifically a dynamic voltage level shifter and integrated circuits including such voltage level shifters.

### BACKGROUND

Integrated circuits that include memory circuits, such as static random-access memory (SRAM) circuits, have writability constraints that are often determined by a minimum operating voltage (Vmin) of an integrated circuit (IC). Often the Vmin required for memory circuits can be higher than the Vmin required for logic circuits of the IC. This discrepancy arises because SRAM cells require a certain voltage threshold to reliably write data, which can be higher than the voltage required for standard logic operations. Consequently, the entire IC's Vmin can be dictated by the memory circuit's Vmin requirements, which in turn, leads to suboptimal power efficiency for the logic circuits of the IC.

To improve power use efficiency, a split power rail architecture can be employed where separate power rails for memory and logic circuits of an IC are controlled independently. To ensure that memory cells (e.g., SRAM memory cells) of a write data output memory circuit have reliable writability, a power rail, dedicated to power a memory circuit domain part of the IC, is maintained at a higher voltage (Vdd_mem or VddH) than the voltage (Vdd_logic or VddL) for a power rail dedicated to power a logic circuit domain of the IC. By implementing such split rail power management, voltage supplies can be tailored to the specific needs of memory and logic circuit domains, thereby reducing overall power requirements and improving overall power efficiency.

### SUMMARY

One aspect is a dynamic voltage level shifter circuit that includes first, second and third set of series-connected transistors. The first set is connected to an input power at a first voltage, an input data signal at a second voltage and a clock signal at the first voltage. The second is connected to the input power at the first voltage, a complement of the input data signal at a second voltage and the clock signal at the first voltage. The third set is cross-connected to receive a level shifted output signal at a low short circuit current at the first voltage from the first set of series-connected transistors and is cross-connected to receive a level shifted complement of the output data signal at the low short circuit current at the first voltage from the second set of series-connected transistors.

Another aspect is an integrated circuit that includes an input power domain connected to transmit input data signals and complement input data signals to an output power domain that includes the dynamic voltage level shifter circuits, and transmit the level shifted output signal and the complement the level shifted output signal.

### BRIEF DESCRIPTION

Reference is now made to the following descriptions taken in conjunction with the accompanying drawings, in which:

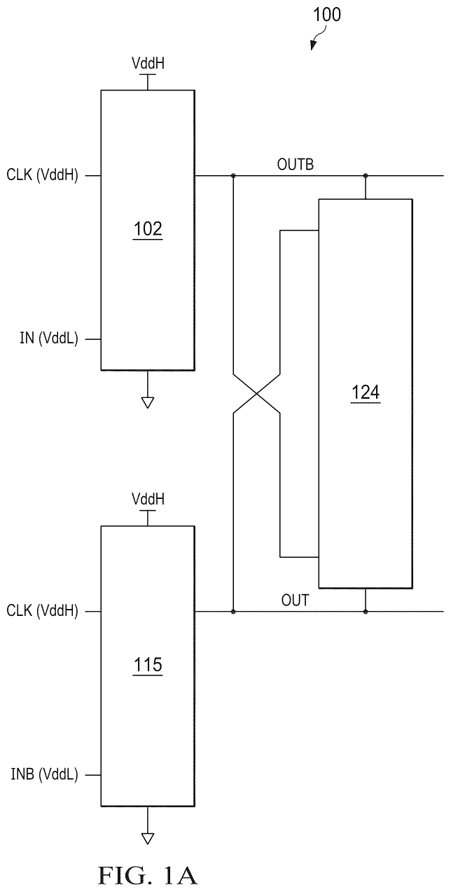

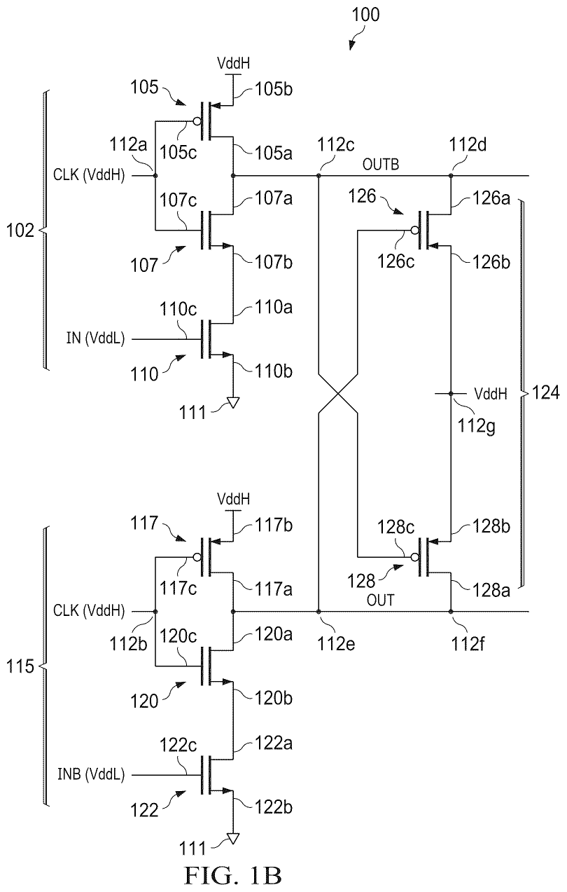

FIG. 1A present a block circuit diagram of an example embodiment of a dynamic voltage level shifter of the disclosure;

FIG. 1B presents a circuit diagram of an example embodiment of a dynamic voltage level shifter of the disclosure;

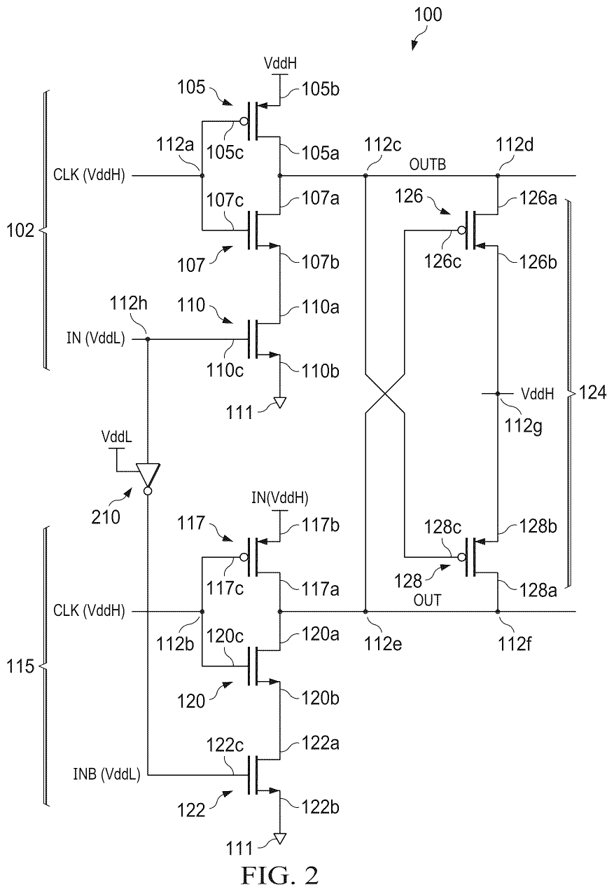

FIG. 2 presents a circuit diagram of another example embodiment of a dynamic voltage level shifter of the disclosure analogous to the circuit shown in FIG. 1A or 1B further including an inverter;

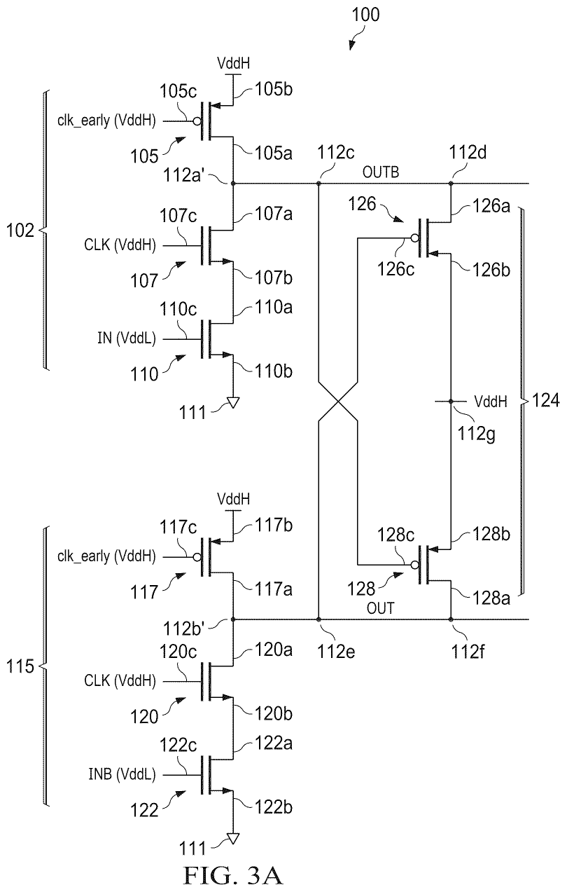

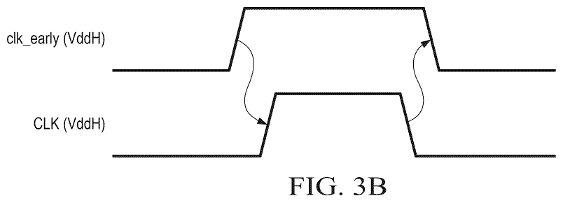

FIG. 3A presents a circuit diagram of another example embodiment of a dynamic voltage level shifter of the disclosure;

FIG. 3B presents an example schematic clock timing diagram for an example circuit diagram such as shown in FIG. 3A;

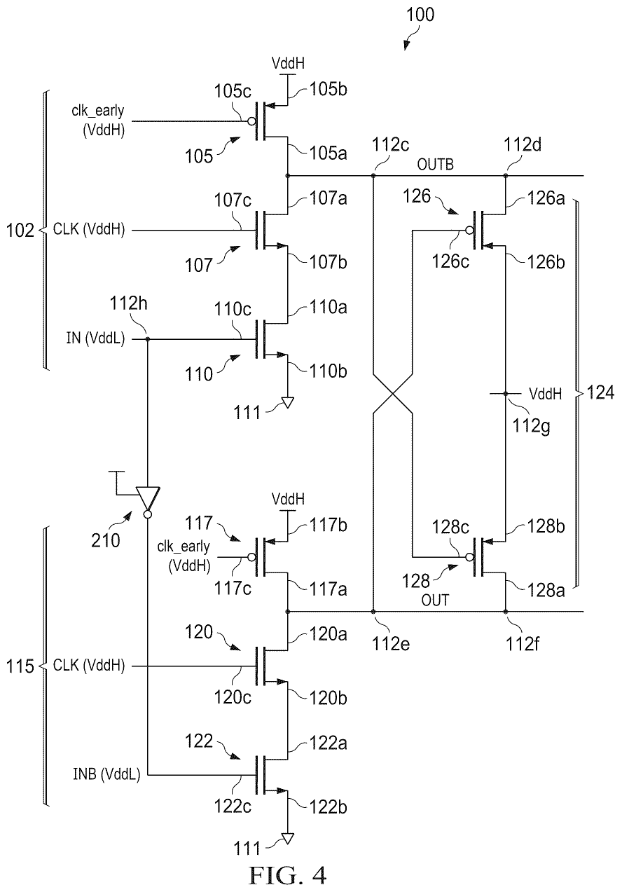

FIG. 4 presents a circuit diagram of another example embodiment of a dynamic voltage level shifter of the disclosure analogous to the circuit shown in FIG. 3A and further including an inverter;

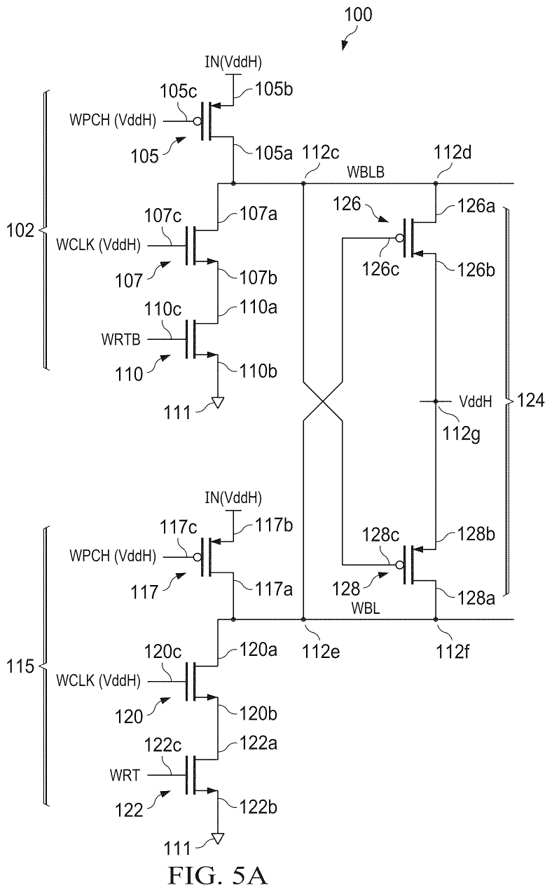

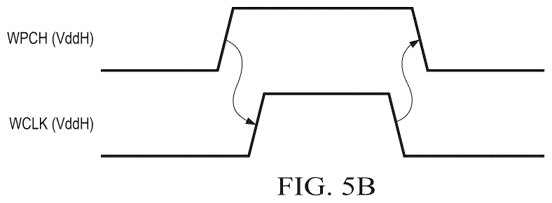

FIG. 5A presents a circuit diagram of another example embodiment of a dynamic voltage level shifter of the disclosure;

FIG. 5B presents an example schematic clock timing diagram for an example circuit diagram such as shown in FIG. 5A;

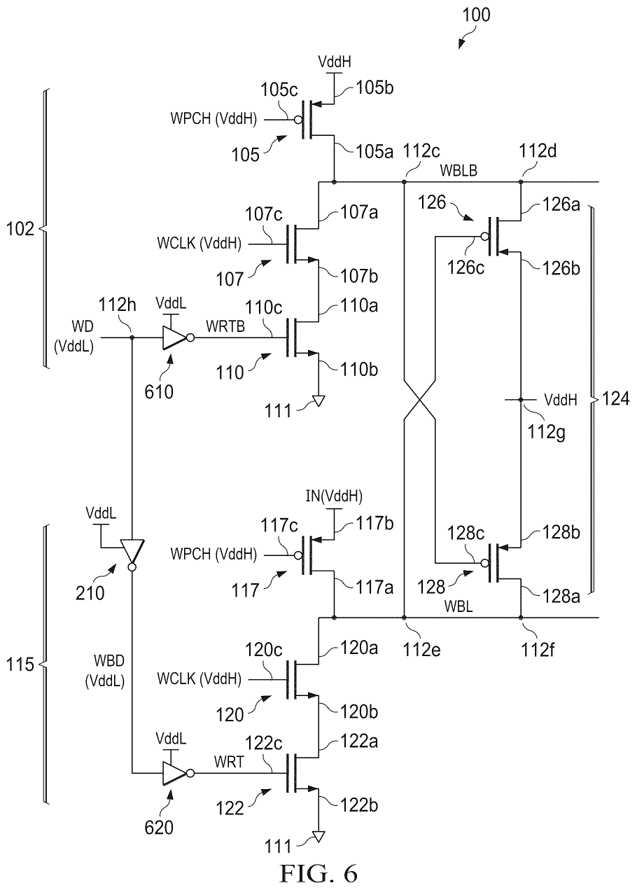

FIG. 6 presents a circuit diagram of another example embodiment of a dynamic voltage level shifter of the disclosure analogous to the circuit shown in FIG. 5A and further including inverters;

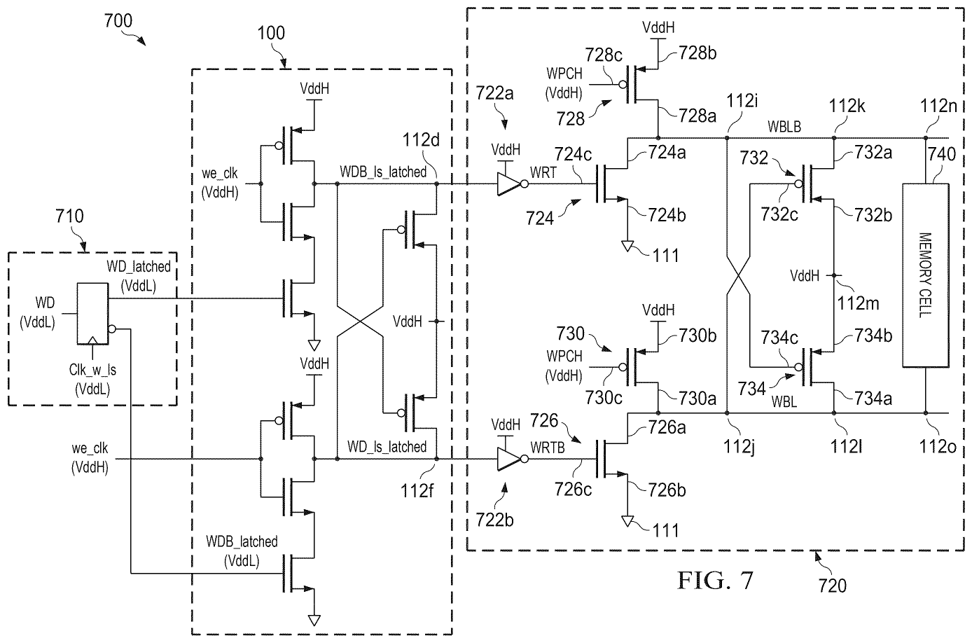

FIG. 7 presents an embodiment of the dynamic voltage level shifter analogous to that shown in FIG. 1 and further including an input latch circuit and a write data output memory circuit;

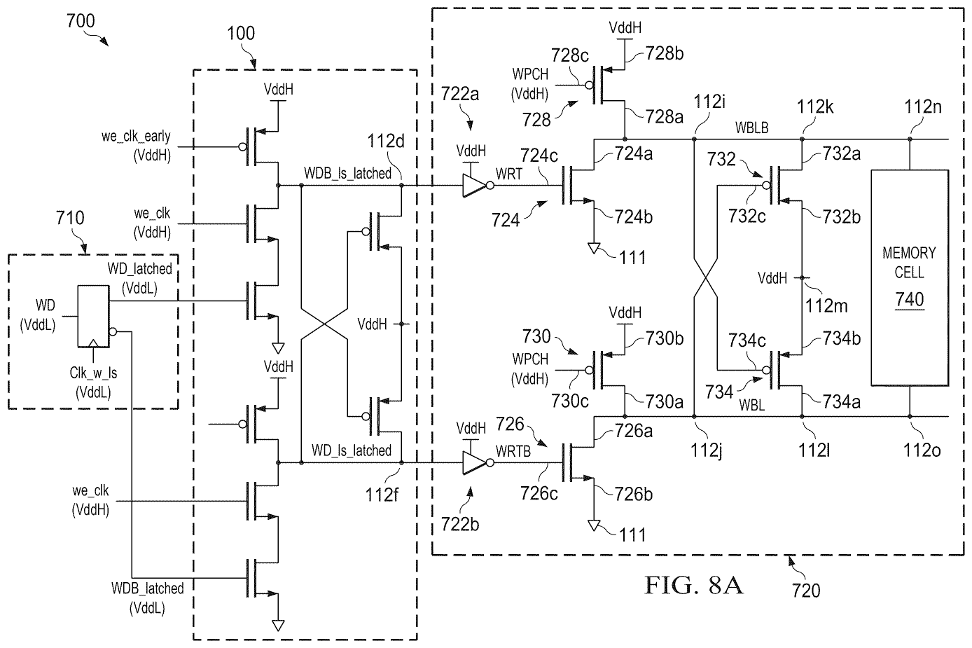

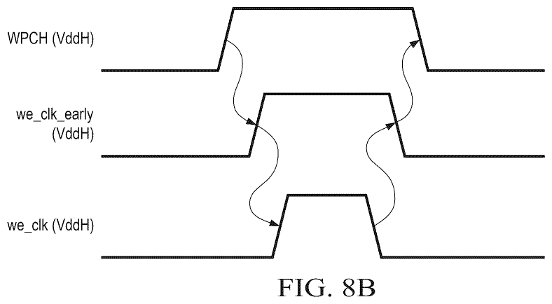

FIG. 8A presents an embodiment of the dynamic voltage level shifter analogous to that shown in FIG. 3A and further including an input latch circuit and a write data output memory circuit;

FIG. 8B presents an example schematic clock timing diagram for an example circuit diagram such as shown in FIG. 58;

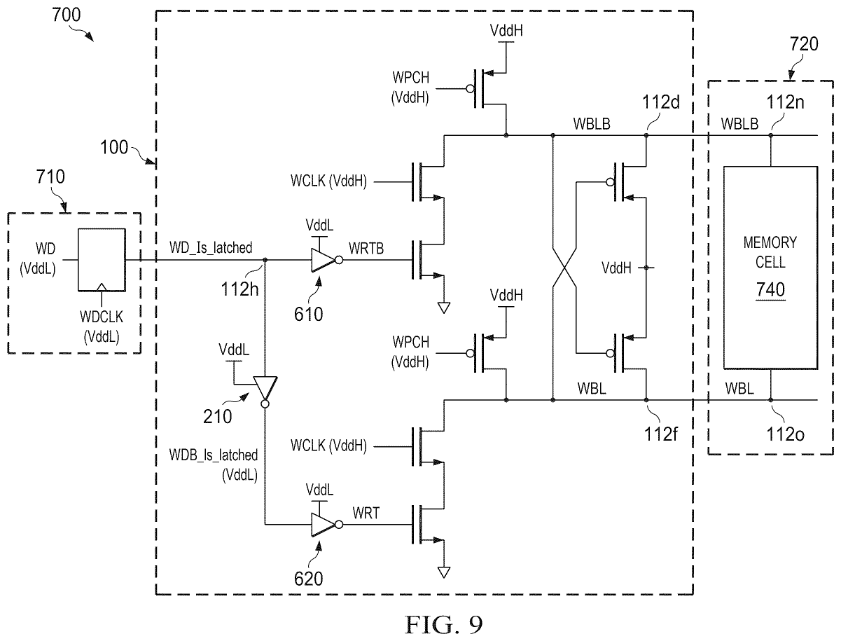

FIG. 9 presents an embodiment of the dynamic voltage level shifter analogous to that shown in FIG. 6 and further including an input latch circuit and a write data output memory circuit;

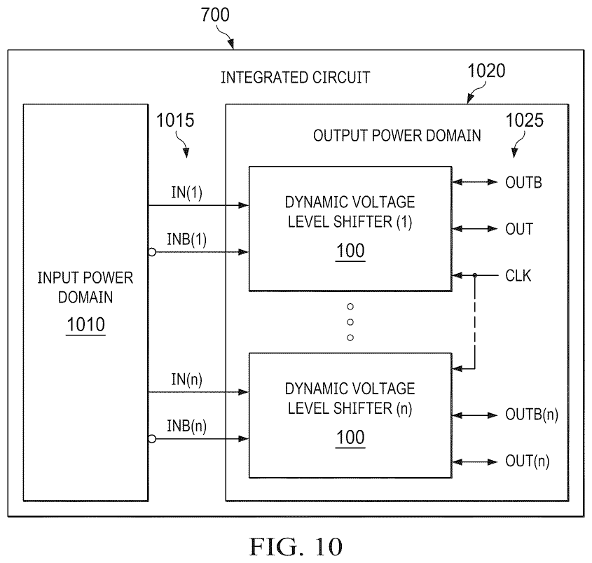

FIG. 10 presents a block diagram of an integrated circuit that includes any embodiments of the dynamic voltage level shifter as disclosed herein including any of the dynamic voltage level shifter embodiments discussed in the context of FIGS. 1-9; and

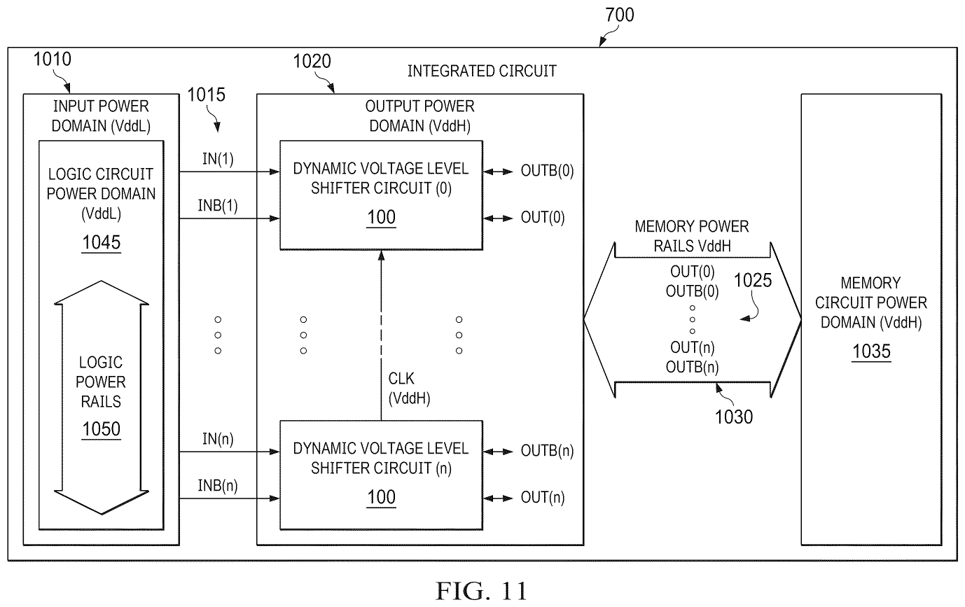

FIG. 11 presents a block diagram of an integrated circuit that includes any embodiments of the dynamic voltage level shifter as disclosed herein.

### DETAILED DESCRIPTION

While split rail architecture presents a promising solution to optimize power consumption by lowering the logic rail voltage independent of the memory rail, as part of the present disclosure we recognized several challenges and propose solutions to these challenges.

One challenge when using such a split rail power architecture is the necessity for voltage level shifting. All inputs and outputs between the memory circuit and the logic circuit must be dynamically voltage-level-shifted back and forth between Vdd_mem and Vdd_logic, respectively. This introduces technical complications such as dynamic power overhead, scalability issues and voltage level shifter delays.

Dynamic power overhead inefficiencies occur because each write operation (e.g., write data operations, WD) causes energy consumption regardless of the clock (clk) phase (e.g., high or low). As an example of scalability issue, consider a memory circuit configuration having arrays of 64×180 SRAM circuits repeated 6000 time on an IC chip. Such a configuration will have 180 input pins, each coupled to its own a voltage level shifter, which repeated 6000 times, results in the need for about 1 million voltage level shifters in the IC. This, in turn, results in increased dynamic power consumption by the voltage level shifters and increased areas of the chip dedicated to the voltage level shifter circuits. Voltage level shifter delays also can affect the overall performance of the chip when both supplies are in same voltage domain, due to the stack of PMOSs that is quite weak compared to NMOS pull-down network and the trip-point shifted toward Vdd_mem.

As further disclosed herein, addressing these challenges requires a new dynamic voltage level shifter design, and connection strategy, to minimize the energy overhead of such voltage level shifters, and, efficiently manage their integration into the overall chip architecture. Our solution improves both power efficiency and area efficiency through the usage of novel dynamic voltage level shifter circuits. Reducing short-circuit power, placing the input latch at the logic voltage domain, and optimizing the design of the IC chip using our dynamic voltage level shifter circuits, improves energy consumption. IC chip area utilization can be improved by reducing the size of N-channel Metal-oxide Semiconductor (NMOS) transistors in the voltage level shifter circuits, now acceptable because there is less source circuit current, by introducing a write-enable clock (we_clk) to isolate the memory circuit high voltage domain from the logic circuit low voltage domain.

One embodiment of the disclosure is a dynamic voltage level shifter circuit. FIG. 1A presents a circuit diagram of an example embodiment of a dynamic voltage level shifter circuit 100 of the disclosure.

The circuit includes a first set of series-connected transistors 102 connected to an input power at a first voltage VddH, an input data signal at a second voltage (IN(VddL)) and a clock signal at the first voltage VddH. Also included is a second set of series-connected transistors 115 connected to the input power at the first voltage VddH, a complement of the input data signal at a second voltage (IN(VddL)) and the clock signal at the first voltage VddH. Further included is a third set of series-connected transistors 124 cross-connected to receive a level shifted output signal at a low short circuit current at the first voltage (OUT(VddH)) from the first set of series-connected transistors 102 and cross-connected to receive a level shifted complement of the output data signal at the low short circuit current at the first voltage (OUTB(VddH)) from the second set of series-connected transistors 115.

As illustrated in FIG. 1B, for some embodiments of the circuit, the first set of series-connected transistors 102 includes a first PMOS transistor 105 and a first and a second NMOS transistor (107, 110). The first PMOS transistor 105 can be connected to an input power at a first voltage VddH and the first PMOS transistor can be connected to a drain 107a of the first NMOS transistor. A source 107b of the first NMOS transistor 107 can be connected to the drain 110a of the second NMOS transistor 110 and the source 110b of the second NMOS transistor can be connected to ground 111.

As also illustrated in FIG. 1B, for some embodiments, the second set of series-connected transistors 115 includes a second PMOS transistor 117 and a third and a fourth NMOS transistor (120, 122). The the second PMOS transistor 117 can be connected to the input power at the first voltage VddH and to a drain 120a of the third NMOS transistor 120 and a source 120b of the third NMOS transistor can be connected to the drain 122a of the fourth NMOS transistor 122 and the source 122b of the fourth NMOS transistor 122 can be connected to the ground 111.

As further illustrated in FIG. 1B, for some embodiments, the third set of series-connected transistors 124 includes a third and a fourth PMOS transistor (126, 128). A source 126b of the third PMOS transistor 126 can be connected to a source 128a of the fourth PMOS transistor 128. A third node 112c, connected to the first PMOS transistor 105 and the drain 107a of the first NMOS transistor 107, can be connected to a fourth node 112d connected to a drain 126a of the third PMOS transistor 126 and cross-connected to a gate 128c of the fourth PMOS transistor 128. The fourth node 112d can carry (e.g., be connected to carry) the level shifted complement output data signal at the low short circuit current at the first voltage (OUTB(VddH)). A fifth node 112e, can be connected to the second PMOS transistor 117 and the drain 120a of the third NMOS transistor 120, can be connected to a sixth node 112f connected to a drain 128a of the fourth PMOS transistor 128 and cross-connected to a gate 126c of the third PMOS transistor 126. The sixth node 112f can carry (e.g., be connected to carry) the level shifted output signal at the low short circuit current at the first voltage (OUT(VddH)). A seventh node 112g can be connected to a source 126b of the third PMOS transistor 126 and connected to a source 128b of the fourth PMOS transistor

With continuing reference to FIGS. 1A-1B, in some such embodiments, the low short current circuit current is through the first set of series-connected transistors 102 when an input data signal at a second voltage (IN(VddL)) corresponds to a logic-1 signal and the low short current circuit current is through the second set of series-connected transistors 115 when a complement of the input data signal at the second voltage (INB(VddL)) corresponds to a logic-1 signal.

This is in contrast to a conventional level shifter (LS) having a high short circuit current, especially, in low to high transition due to drive fight in LS. However, our proposal has the short circuit current that is equivalent to a regular inverter gate that just depends on the input slew and is very low current compared to a conventional LS circuit.

The term low short current circuit current as used herein refers to a lower current attainable using embodiments of the disclosed new dynamic voltage level shifter design, as compared to a higher short circuit current associated with using a conventional voltage level shifter design. As a non-limiting example when the when input data signal at a second voltage is operated at 0.45 V and the first voltage (OUT(VddH) is operated at 1.4 V, the average DC current can be about 20 percent for the disclosed design as compared to the conventional design. One skilled in the pertinent art would understand how the extent to which the low short current circuit could be attained relative to the conventional high shot current circuit would depend upon process, voltage, and temperature (PVT) conditions and specifications of the circuit. As non-limiting examples our lower short current circuit value could range from 10 percent less to 90 less than the higher conventional short current circuit.

With continuing reference to FIGS. 1A-1B, in some such embodiments, the first PMOS transistor 105 can be connected to the input power at the first voltage VddH by a drain 105a of the first PMOS transistor, and, the first PMOS transistor can be connected to the drain 107a of the first NMOS transistor 107 by a source 105b of the first PMOS transistor, and, a gate 105c of the first PMOS transistor 105 and a gate 107c of the first NMOS transistor 107 can be connected by a first node 112a carrying a clock signal at the first voltage (clk(VddH)), and a gate 110c of the second NMOS transistor 110 can be connected to an input data signal at a second voltage (IN(VddL)).

Further, in some such embodiments, the second PMOS transistor 117 can be connected to the input power at the first voltage (VhhH) by a drain 117a of the second PMOS transistor, and, the second PMOS transistor can be connected to the drain 120a of the third NMOS transistor 120 by a source 117b of the second PMOS transistor, a gate 117c of the second PMOS transistor 117 and a gate 120c of the third NMOS transistor 120 can be connected by a second node 112b carrying the clock signal at the first voltage (clk(VddH)), and a gate 122c of the fourth NMOS transistor 122 can be connected to a complement of the input data signal at the second voltage (INB(VddL)).

As illustrated in FIG. 2, some embodiments of the circuit 100 includes an inverter 210, powered by the second voltage (VddL). The invertor 210 can be connected to an eighth node 112h connecting the gate 110c of the second NMOS transistor 110 and the gate 122c of the fourth NMOS transistor 122. The inverter inverts the input data signal (IN) to a complement of the Input data signal (INB). One skilled in the pertinent art would appreciate that a variety of inverter circuits, or other circuits, could be used to produce a complement of the input data signal.

FIG. 3A presents another embodiment of the circuit 100 featuring no short circuit between the first PMOS and first NMOS transistors and second PMOS and third NMOS transistors (e.g., no first or second nodes 112a, 112b) and no inverter.

As illustrated, the first PMOS transistor 105 can be connected to the input power at the first voltage (VddH) by a source 105b of the first PMOS transistor, the first PMOS transistor can be connected to the drain 107a of the first NMOS transistor by a drain 105a of the first PMOS transistor by a first node 112a′. A gate 105c of the first PMOS transistor can be connected to an early clock signal at the first voltage (clk_early(VddH)) A gate 107c of the second NMOS transistor 107 can be connected to a clock signal at the first voltage (clk(VddH)). A gate 110c of the second NMOS transistor 110 can be connected to a input data signal at a second voltage (IN(VddL)).

As further illustrated the second PMOS transistor 117 can be connected to the input power at the first voltage IN(VddH) by a source 117b of the second PMOS transistor and connected to the drain 120a of the third NMOS transistor 120 by a drain 117a of the second PMOS transistor by a second node 112b′. A gate 117c of the second PMOS transistor can be connected to the early clock signal at the first voltage (clk_early(VddH)). A gate 120c of the third NMOS transistor 120 can be connected the clock signal at the first voltage (we_clk(VddH)). A gate 122c of the fourth NMOS transistor 122 can be connected to a complement of the input data signal at the second voltage (INB(VddL)).

The terms early clock signal (clk_early) and clock (clk) refer to signals to control PMOS gates (e.g., gates 105c, 117c) and NMOS gates (e.g., gates 107c, 120c) respectively. The we_clk and we_clk_early signals can be generated in a control block that are the result of the clk signal gated with the write enable signal, to ensure toggling when there is a write operation. As illustrated in FIG. 3B, these two signals can be time sequenced to ensure there would not substantially any DC path from VDD to ground when the bottom NMOS input state is logic-1. E.g., as illustrated, the clk signal rises after clk_early rises, and falls before clk_early falls to ensure that there is no DC path. This circuit embodiment can eliminate the need for the short circuit current such as shown for the embodiments depicted in FIGS. 1B-2.

In some such embodiments, however, the circuit can include an inverter such as illustrated in FIG. 4. The inverter 210 can be connected to an eighth node 112h connecting to the gate 110c of the second NMOS transistor 110 and the gate 122c of the fourth NMOS transistor 122. The inverter inverts the input data signal at the second voltage (IN(VddL)) to a complement of the input data signal at the second voltage (INB(VddL)).

FIG. 5A presents still another embodiment of the circuit 100, featuring no short circuit between the first PMOS and first NMOS transistors and second PMOS and third NMOS transistors (e.g., no first or second nodes 112a, 112b), no inverter, and, a reuse of the write driver instead of clk_early.

As illustrated, the first PMOS transistor 105 can be connected to the input power at the first voltage (VddH) by a source 105b of the first PMOS transistor. The first PMOS transistor can be connected to the drain 107a of the first NMOS transistor 107 by a drain 105a of the first PMOS transistor. A gate 105c of the first PMOS transistor 105 can be connected to a write bit-line pre-charge clock signal at the first voltage (wpch, (VddH)). A gate 107c of the first NMOS transistor 107 can be connected to a write-enable clock signal at the first voltage (wclk(VddH)). A gate 110c of the second NMOS transistor 110 can be connected to a complement write driver pull-down signal at the second voltage (wrtb(VddL)).

As further illustrated, the second PMOS transistor 117 can be connected to the input power at the first voltage IN(VddH) by a source 117b of the second PMOS transistor. The second PMOS transistor can be connected to the drain 120a of the third NMOS transistor 120 by a drain 117a of the second PMOS transistor. A gate 117c of the second PMOS transistor 117 can be connected to the write bit-line pre-charge signal at the first voltage (wpch(VddH)). A gate 120c of the third NMOS transistor 120 can be connected to the write-enable clock signal at the first voltage (wclk(VddH)). The gate 122c of the fourth NMOS 122 can be connected to a write driver pull-down signal at the second voltage (wrt(VddL)).

The circuit embodiment depicted in FIG. 5A is similar to the embodiment shown in FIG. 3A except that the clk_early and clk signals are replaced by wpch and wclk signals, respectively. Effectively, this reuses the write driver signal (WD) for level shifting at the same time as it is used for dynamic logic. As illustrated in FIG. 5B, these two signals are time sequenced to ensure there would not be substantially any DC path from VDD to ground when the bottom NMOS input state is logic-1. E.g., as illustrated, the wclk signal rises after wpch rises, and falls before wclk falls to ensure that there is no DC path. Again, this circuit embodiment can eliminate the need for the short circuit current such as shown for the embodiments depicted in FIGS. 1-2.

In some such embodiments, however, the circuit can include an inverter such as illustrated in FIG. 6. A first inverter 210 can be connected to an eighth node 112h and connected to a second inverter 610 connected between the eight node 112h and the gate 110c of the second NMOS transistor 110. The first inverter 210 also can be connected to a third inverter 620 connected between the first inverter 210 and the gate 122c of the fourth NMOS transistor 122. The inverters 210, 610, 620 invert a write data signal at the second voltage (WD(VddL)) to the complement write driver pull-down signal (wrtb) connected to the gate 110c of the second NMOS transistor 110, and, to the write driver pull-down signal (wrt) connected to the gate 122c of the fourth NMOS transistor 122. The inverters 210, 610, 620 can be powered by the second voltage (VddL),

For any embodiments of the circuits 100 disclosed herein, the first voltage VddH can be greater than the second voltage VddL.

For any embodiments of the circuits 100 disclosed herein, one or more of the PMOS transistors (e.g., one or more of PMOS transistors 105, 117, 126. 128) can be two-fin field effect transistors and one or more of the NMOS transistors (e.g., one or more of NMOS transistors 107, 110, 120, 122) can be two-, three-, or four-fin filed effect transistors or combinations thereof.

As illustrated in FIG. 7, embodiments of the voltage level shifter circuit 100 (e.g., FIGS. 1A-1B) can be part of an integrated circuit 700 that includes a latch circuit 710.

As illustrated the latch circuit 710 can receive (e.g., connected to receive) an input write data signal (WD), transmit (e.g., connected to transmit) the input data signal (FIG. 1 IN(VddL)) as a write data latched signal (WD_latched) connected to the gate 110c of the second NMOS transistor 110 (FIG. 1), and transmit the complement input data signal (FIG. 1 INB(Vddl) as a complement write data latched signal (WDB_latched) connected to the gate 122c of the fourth NMOS transistor 122 (FIG. 1). The clock signal (clk, FIG. 1) can be a write enable clock signal (we_clk), the level shifted complement output data signal (OUTB, FIG. 1) can be a level shifted complement write data latched signal (WDB_ls_latched), the level shifted output data signal (OUT, FIG. 1) can be a level shifted write data latched signal (WD_ls_latched), and the latch circuit 710 can be controlled by a level shifted write clock signal at the second voltage (Clk_w_ls (VddL).

The latch circuit 710 can have two phases: opaque or transparent. The latch circuit can be transparent at the low phase of the clock, at that time it samples the input. At the high phase of the clock, it is opaque, and an evaluation operation can be performed inside the latch circuit, as familiar to one skilled in the pertinent art.

As further illustrated in FIG. 7 the integrated circuit 700 can additionally or alternatively further includes a memory circuit 720. The memory circuit can include a first inverter 722a and a second inverter 722b. The first inverter 722a can be connected to the fourth node 112d to convert the level shifted complement write data latched signal (WDB_ls_latched) to a write signal (wrt) that can be connected to a gate 724c of a first NMOS transistor 724 of the memory circuit 720. The second inverter 722b can be connected to the sixth node 112f to convert the level shifted write data latched signal (WD_ls_latched) to a complement write signal (wrtb) that can be connected to a gate 726c of a second NMOS transistor 726 of the memory circuit 720.

A drain 728a of a first PMOS transistor 728 of the memory circuit 720 can be connected to a drain 724a of the first NMOS transistor 724 of the memory circuit 720 by a first node 112i of the memory circuit 720 to thereby convert the write signal (wrt) to a complement write bit-line signal (WBLB). A drain 730a of a second PMOS transistor 730 of the memory circuit 720 can be connected to a drain 726a of the second NMOS transistor 726 of the memory circuit 720 by a second node 112j of the memory circuit 720 to thereby convert the complement write signal (wrtb) to a write bit-line signal (WBL). A source 724b of the first NMOS transistor 724 of the memory circuit 720 and a source 726b of the second NMOS transistor 726 of the memory circuit can both be connected to ground 111. A gate 732c and a drain 732a of a third PMOS transistor 732 of the memory circuit 720 can be connected to the second node 112j and a third node 112k of the memory circuit 720, respectively. A gate 734c and a source 734b of a fourth PMOS transistor 734 of the memory circuit 720 can be connected to the first node 112i and a fourth node 112l of the memory circuit 720, respectively. A source 734b of the fourth PMOS transistor 734 of the memory circuit 720 can be connected to source 732b of the third transistor 732 of the memory circuit 720 by a fifth node 112m of the memory circuit 720. The gate 728c of the first PMOS transistor 728 of the memory circuit 720 and the gate 730c of the second PMOS transistor 730 can be separately connected (e.g., via separate conductive lines) to a write pre-charge signal at the first voltage (wpch (VDDH)). The complement write bit-line signal (WBLB) and the write bit-line signal (WBL) can be connected to a memory cell 740 of the memory circuit 720 by a sixth node 112n and a seventh node 112o of the memory circuit, respectively.

FIG. 8A illustrates another embodiment of the voltage level shifter circuit 100 (e.g., FIG. 3B) that can be part of an integrated circuit 700 that includes a latch circuit 710.

The latch circuit 710 can receive an input write data signal (WD), transmit the input data signal (FIG. 3A, IN(VddL)) as a write data signal (WD) and convert to a write data latched signal (WD_latched) connected to the gate 110c of the second NMOS transistor 110 (FIG. 3A), and convert to a complement write data latched signal (WDB_latched) connected to the gate 122c of the fourth NMOS transistor 122 (FIG. 3A). The early clock signal (FIG. 3A clk_early(VddH)) can be a write enable early clock signal (we_clk_early), the clock signal (clk, FIG. 3A) can be a write enable clock signal (we_clk), the level shifted complement output data signal (OUTB, FIG. 3A) can be a level shifted complement write data latched signal (WDB_ls_latched), the level shifted output data signal (OUT, FIG. 3A) can be a level shifted write data latched signal (WD_ls_latched) and the latch circuit 710 can be controlled by a level shifted write clock signal at the second voltage (Clk_w_ls(VddL)).

As further illustrated in FIG. 8A, the integrated circuit 700 can additionally or alternatively further include a memory circuit 720. Analogous to that described in the context of FIG. 7 the memory circuit can include a first inverter 722a and a second inverter 722b. The first inverter 722a can be connected to the fourth node 112d to convert the level shifted complement write data latched signal (WDB_ls_latched) to a write signal (wrt) that can be connected to a gate 724c of a first NMOS transistor 724 of the memory circuit 720. The second inverter 722b can be connected to the sixth node 112f to convert the level shifted write data latched signal (WD_ls_latched) to a complement write signal (wrtb) that can be connected to a gate 726c of a second NMOS transistor 726 of the memory circuit 720.

A drain 728a of a first PMOS transistor 728 of the memory circuit 720 can be connected to a drain 724a of the first NMOS transistor 724 of the memory circuit 720 by a first node 112i of the memory circuit 720 to thereby convert the write signal (wrt) to a complement write bit-line signal (WBLB). A drain 730a of a second PMOS transistor 730 of the memory circuit 720 can be connected to a drain 726a of the second NMOS transistor 726 of the memory circuit 720 by a second node 112j of the memory circuit 720 to thereby convert the complement write signal (wrtb) to a write bit-line signal (WBL). A source 724b of the first NMOS transistor 724 of the memory circuit 720 and a source 726b of the second NMOS transistor 726 of the memory circuit can both be connected to ground 111. A gate 732c and a drain 732a of a third PMOS transistor 732 of the memory circuit 720 can be connected to the second node 112j and a third node 112k of the memory circuit 720, respectively. A gate 734c and a source 734b of a fourth PMOS transistor 734 of the memory circuit 720 can be connected to the first node 112i and a fourth node 112l of the memory circuit 720, respectively. A source 734b of the fourth PMOS transistor 734 of the memory circuit 720 can be connected to source 732b of the third transistor 732 of the memory circuit 720 by a fifth node 112m of the memory circuit 720. The gate 728c of the first PMOS transistor 728 of the memory circuit 720 and the gate 730c of the second PMOS transistor 730 can be separately connected (e.g., via separate conductive lines) to a write pre-charge signal at the first voltage (wpch (VDDH)). The complement write bit-line signal (WBLB) and the write bit-line signal (WBL) can be connected to a memory cell 740 of the memory circuit 720 by a sixth node 112n and a seventh node 112o of the memory circuit, respectively.

As illustrated in FIG. 8B, the three clock signals, write enable clock early (we_clk_early), write enable clock (we_clk) and write pre-charge clock (wpch) can be time sequenced to ensure there would substantially not be any DC path from VDD to ground when the bottom NMOS input state is logic-1. E.g., as illustrated, the we_clk rises after we_clk_early rises, we_clk_early rises after wpch rises, we_clk falls before we_clk_early falls, and we_clk_early falls before wpch falls to ensure that there is no DC path. In turn, this arrangement can eliminate the need for the short circuit current such as shown for the embodiments depicted in FIGS. 1-2

FIG. 9 illustrates another embodiment of the voltage level shifter circuit 100 (e.g., FIG. 6) that can be part of an integrated circuit 700 that includes a latch circuit 710. The latch circuit 710 can receive the write data signal at the second voltage WD(VddL) and transmit a write drive level shifted latched signal (WD_ls_latched) to the eighth node 112h. The first inverter 210 (FIG. 6) can convert the write drive level shifted latched signal to a complement write drive level shifted latched signal (WDB_ls_latched). The third inverter 620 (FIG. 6) can convert the complement write drive level shifted latched signal to the write driver pull-down signal at the second voltage (wrt(VddL)). The second inverter 610 converts the write drive level shifted latched signal to the complement write driver pull-down signal at the second voltage (wrtb(VddL)) and the latch circuit 710 is controlled by a write drive clock signal at the second voltage (wdclk(VddL)).

The two clock signals, write clock (w_clk) and write pre-charge clock (wpch) can be time sequenced similar to as illustrated and described in the context of FIG. 5B.

As also illustrated, the integrated circuit 700 can additionally or alternatively further include a memory circuit 720. The fourth node 112d of the circuit 100 can connect the write bit-line complement signal (WBLB, FIG. 6) and the sixth node 112f of the circuit 100 can connect the write bit-line signal (WBL, FIG. 6) to a sixth node 112n and a seventh node 112o of a memory cell 740 of the memory circuit 720, respectively.

Another embodiment of the disclosure is an integrated circuit that includes any of the disclosed embodiments of dynamic voltage level shifter circuits.

As illustrated in FIG. 10, the integrated circuit 700 can include an input power domain 1010 connected to transmit input data signals (IN(1) . . . IN(n) and complement input data signal (IN(1) . . . IN(n) and INB(1) . . . INB(n) generally 1015) to an output power domain 1020 that includes any embodiments of the dynamic voltage level shifter circuits 100 (e.g., dynamic voltage level shifter (1) . . . dynamic voltage level shifter (n)), and transmit the level shifted the level shifted output signal (OUT) and the complement the level shifted output signal (OUTB) (generally, level shifted output 1025).

As non-limiting examples, in some embodiments, the input power domain 1010 can be a value ranging for 0.3 V to 0.7 V and the output power domain can be a higher value ranging from 0.8 V to 1.6 V depending on the process node implemented including performance and power consumption targets.

In some such embodiments, the transmission of the level shifted output signals (OUT) and the complement the level shifted output signals (OUTB) from the dynamic voltage level shifter circuits 100 can be controlled by a clock signal (CLK) applied to the first and second sets of series-connected transistors (e.g., FIG. 1A transistor sets 102, 115) of the dynamic voltage level shifter circuits 100.

For example, as familiar to one skilled in the pertinent art, at an idle stage of operation, the dynamic level shifter circuits 100 can be kept pre-charged, and at an evaluation stage, the input data signal or complement input data signal at a second voltage (e.g., IN and INB, respectively, or in some embodiments, WD_ls and WDB_ls, respectively) can be discharged through the second and fourth NMOS transistors 110, 122 (FIG. 1B) of the first and second sets of series-connected transistors 102, 115, respectively.

FIG. 11 illustrates another embodiment of the integrated circuit showing a memory circuit power domain 1035.

The memory circuit power domain 1035 can connect to the output power domain 1020 by memory power rails 1030 carrying the level shifted the level shifted output signals (OUT(0) . . . OUT(n), 1025) and the complement the level shifted output signals (OUTB(0) . . . OUTB(n), 1025) there-to.

The input power domain 1010 can include a logic circuit power domain 1045. The logic circuit power domain 1045 further includes one or more logic circuit power rails 1050 at the second voltage VddL.

Those skilled in the art to which this application relates will appreciate that other and further additions, deletions, substitutions and modifications may be made to the described embodiments.

What is claimed is:

1. A dynamic voltage level shifter circuit, comprising:
a first set of series-connected transistors connected to an input power at a first voltage, an input data signal at a second voltage and a clock signal at the first voltage;
a second set of series-connected transistors connected to the input power at the first voltage, a complement of the input data signal at a second voltage and the clock signal at the first voltage; and
a third set of series-connected transistors cross-connected to receive a level shifted output signal at a low short circuit current at the first voltage from the first set of series-connected transistors and cross-connected to receive a level shifted complement of the output data signal at the low short circuit current at the first voltage from the second set of series-connected transistors.

2. The circuit of claim 1, wherein
the first set of series-connected transistors includes a first PMOS transistor and a first and a second NMOS transistor, wherein:
the first PMOS transistor is connected to an input power at a first voltage and the first PMOS transistor is connected to a drain of the first NMOS transistor; and
a source of the first NMOS transistor is connected to the drain of the second NMOS transistor and the source of the second NMOS transistor is connected to ground.

3. The circuit of claim 2, wherein
the second set of series-connected transistors includes a second PMOS transistor and a third and a fourth NMOS transistor, wherein:
the second PMOS transistor is connected to the input power at the first voltage and to a drain of the third NMOS transistor, a source of the third NMOS transistor is connected to the drain of the fourth NMOS transistor and the source of the fourth NMOS transistor is connected to the ground.

4. The circuit of claim 3, wherein
the third set of series-connected transistors includes a third and a fourth PMOS transistor, wherein:
a source of the third PMOS transistor is connected to a source of the fourth PMOS transistor;
a third node, connected to the first PMOS transistor and the drain of the first NMOS transistor, is connected to a fourth node connected to a drain of the third PMOS transistor and cross-connected to a gate of the fourth PMOS transistor, wherein the fourth node carries the level shifted complement output data signal at the low short circuit current at the first voltage;
a fifth node, connected to the second PMOS transistor and the drain of the third NMOS transistor, is connected to a sixth node connected to a drain of the fourth PMOS transistor and cross-connected to a gate of the third PMOS transistor, wherein the sixth node carries the level shifted output signal at the low short circuit current at the first voltage; and
a seventh node connected to a source of the third PMOS transistor and connected to a source of the fourth PMOS transistor.

5. The circuit of claim 1, wherein the low short current circuit current is through the first set of series-connected transistors when an input data signal at a second voltage corresponds to a logic-1 signal and the low short current circuit current is through the second set of series-connected transistors when a complement of the input data signal at the second voltage corresponds to a logic-1 signal.

6. The circuit of claim 3, wherein:
the first PMOS transistor is connected to the input power at the first voltage by a drain of the first PMOS transistor, and, the first PMOS transistor is connected to the drain of the first NMOS transistor by a source of the first PMOS transistor, and, a gate of the first PMOS transistor and a gate of the first NMOS transistor are connected by a first node carrying a clock signal at the first voltage, and a gate of the second NMOS transistor is connected to an input data signal at a second voltage; and
the second PMOS transistor is connected to the input power at the first voltage by a drain of the second PMOS transistor, and, the second PMOS transistor is connected to the drain of the third NMOS transistor by a source of the second PMOS transistor, a gate of the second PMOS transistor and a gate of the third NMOS transistor are connected by a second node carrying the clock signal at the first voltage, and a gate of the fourth NMOS transistor is connected to a complement of the input data signal at the second voltage.

7. The circuit of claim 6, further including an inverter, powered by the second voltage, connected to an eighth node connecting the gate of the second NMOS transistor and the gate of the fourth NMOS transistor, wherein the inverter inverts the input data signal to a complement of the input data signal.

8. The circuit of claim 4, wherein:
the first PMOS transistor is connected to the input power at the first voltage by a source of the first PMOS transistor, the first PMOS transistor is connected to the drain of the first NMOS transistor by a drain of the first PMOS transistor by a first node, a gate of the first PMOS transistor is connected to an early clock signal at the first voltage, a gate of the second NMOS transistor is connected to a clock signal at the first voltage, and a gate of the second NMOS transistor is connected to a input data signal at a second voltage; and
the second PMOS transistor is connected to the input power at the first voltage by a source of the second PMOS transistor, the second PMOS transistor is connected to the drain of the third NMOS transistor by a drain of the second PMOS transistor by a second node, a gate of the second PMOS transistor is connected to the early clock signal at the first voltage, a gate of the third NMOS transistor is connected the clock signal at the first voltage, and a gate of the fourth NMOS transistor is connected to a complement of the input data signal at the second voltage.

9. The circuit of claim 8, further including an inverter connected to an eighth node connecting to the gate of the second NMOS transistor and the gate of the fourth NMOS transistor, wherein the inverter inverts the input data signal at the second voltage to a complement of the input data signal at the second voltage.

10. The circuit of claim 4, wherein:
the first PMOS transistor is connected to the input power at the first voltage by a source of the first PMOS transistor, the first PMOS transistor is connected to the drain of the first NMOS transistor by a drain of the first PMOS transistor, a gate of the first PMOS transistor is connected to a write bit-line pre-charge clock signal at the first voltage, a gate of the first NMOS transistor is connected to a write-enable clock signal at the first voltage, a gate of the second NMOS transistor is connected to a complement write driver pull-down signal at the second voltage; and
the second PMOS transistor is connected to the input power at the first voltage by a source of the second PMOS transistor, the second PMOS transistor is connected to the drain of the third NMOS transistor by a drain of the second PMOS transistor, a gate of the second PMOS transistor is connected to the write bit-line pre-charge signal at the first voltage, a gate of the third NMOS transistor is connected to the write-enable clock signal at the first voltage, and the gate of the fourth NMOS is connected to a write driver pull-down signal at the second voltage.

11. The circuit of claim 10, further includes a first inverter connected to an eighth node and connected to a second inverter connected between the eight node and the gate of the second NMOS transistor, the first inverter also connected to a third inverter connected between the first inverter and the gate of the fourth NMOS transistor, wherein the inverters inverts a write data signal at the second voltage to the complement write driver pull-down signal connected to the gate of the second NMOS transistor and to write driver pull-down signal connected to the gate of the fourth NMOS transistor, wherein the inverters are powered by the second voltage.

12. The circuit of claim 1, wherein the first voltage is greater than the second voltage.

13. The circuit of claim 1, wherein the one or more of the PMOS transistors are two-fin field effect transistors and one or more of the NMOS transistors are two-, three-, or four-fin filed effect transistors.

14. The circuit of claim 4, wherein the voltage level shifter circuit is part of an integrated circuit that includes a latch circuit that receives an input write data signal and transmits the input data signal as a write data latched signal connected to the gate of the second NMOS transistor, and transmits the complement input data signal as a complement write data latched signal connected to the gate of the fourth NMOS transistor, and wherein the clock signal is a write enable clock signal, the level shifted complement output data signal is a level shifted complement write data latched signal, the level shifted output data signal is a level shifted write data latched signal, and the latch circuit is controlled by a level shifted write clock signal at the second voltage.

15. The circuit of claim 14, wherein the integrated circuit 700 further includes a memory circuit, the memory circuit including:
a first inverter connected to the fourth node to convert the level shifted complement write data latched signal to a write signal that is connected to a gate of a first NMOS transistor of the memory circuit;
a second inverter connected to the sixth node to convert the level shifted write data latched signal to a complement write signal that is connected to a gate of a second NMOS transistor of the memory circuit;
a drain of a first PMOS transistor of the memory circuit connected to a drain of the first NMOS transistor of the memory circuit by a first node of the memory circuit to thereby convert the write signal to a complement write bit-line signal;
a drain of a second PMOS transistor of the memory circuit connected to a drain of the second NMOS transistor of the memory circuit by a second node of the memory circuit to thereby convert the complement write signal to a write bit-line signal;
a source of the first NMOS transistor of the memory circuit and a source of the second NMOS transistor of the memory circuit are both connected to ground;
a gate and a drain of a third PMOS transistor of the memory circuit are connected to the second node and a third node of the memory circuit, respectively;
a gate and a source of a fourth PMOS transistor of the memory circuit are connected to the first node and a fourth node of the memory circuit, respectively;
a source of the fourth PMOS transistor of the memory circuit is connected to source of the third transistor of the memory circuit by a fifth node of the memory circuit, wherein:
the gate of the first PMOS transistor of the memory circuit and the gate of the second PMOS transistor are separately connected to a write pre-charge signal at the first voltage; and
the complement write bit-line signal and the write bit-line signal are connected to a memory cell of the memory circuit by a sixth node and a seventh node of the memory circuit, respectively.

16. The circuit of claim 8, wherein the voltage level shifter circuit is part of an integrated circuit that includes a latch circuit that receives an input write data signal and transmits the input data signal as a write data signal and converts to a write data latched signal connected to the gate of the second NMOS transistor, and converts to a complement write data latched signal connected to the gate of the fourth NMOS transistor, and wherein:
the early clock signal is a write enable early clock signal, the clock signal is a write enable clock signal, the level shifted complement output data signal is a level shifted complement write data latched signal, the level shifted output data signal is a level shifted write data latched signal and the latch circuit is controlled by a level shifted write clock signal at the second voltage.

17. The circuit of claim 16, wherein the integrated circuit further includes a memory circuit, the memory circuit including:
a first inverter connected to the fourth node to convert the latched complement of the write data signal at the low short circuit current to a write signal that is connected to a gate of a first NMOS transistor of the memory circuit;
a second inverter connected to the sixth node to convert the latched write data sign signal at the low short circuit current to a complement write signal at the first voltage that is connected to a gate of a second NMOS transistor of the memory circuit;
a drain of a first PMOS transistor of the memory circuit is connected to a drain of the first NMOS transistor of the memory circuit by a first node of the memory circuit to thereby convert the write signal to a complement write bit-line signal;
a drain of a second PMOS transistor of the memory circuit is connected to a drain of the second NMOS transistor of the memory circuit by a second node of the memory circuit to thereby convert the complement write signal to a write bit-line signal;
a source of the first NMOS transistor of the memory circuit and a source of the second NMOS transistor of the memory circuit are both connected to ground;
a gate and a drain of a third PMOS transistor of the memory circuit are connected to the second node and a third node of the memory circuit, respectively;
a gate and a drain of a fourth PMOS transistor of the memory circuit are connected to the first node and a fourth node of the memory circuit, respectively;
a source of the fourth PMOS transistor of the memory circuit is connected to source of the third transistor of the memory circuit by a fifth node of the memory circuit;
the complement write bit-line signal and the write bit-line signal are connected to a memory cell of the memory circuit by a sixth node and a seventh node of the memory circuit, respectively.

18. The circuit of claim 11, wherein the voltage level shifter circuit is part of an integrated circuit that includes a latch circuit that receives the write data signal at the second voltage and transmits a write drive level shifted latched signal to the eighth node, wherein the first inverter converts the write drive level shifted latched signal to a complement write drive level shifted latched signal, the third inverter converts the complement write drive level shifted latched signal to the write driver pull-down signal at the second voltage, the second inverter converts the write drive level shifted latched signal to the complement write driver pull-down signal at the second voltage and the latch circuit is controlled by a write drive clock signal at the second voltage.

19. The circuit of claim 18, wherein the integrated circuit further includes a memory circuit, the memory circuit, wherein the fourth node of the circuit connects the write bit-line complement signal and the sixth node of the circuit connects the write bit-line signal to a sixth node and a seventh node of a memory cell of the memory circuit, respectively.

20. An integrated circuit, comprising:
an input power domain connected to transmit input data signals and complement input data signals to an output power domain that includes the dynamic voltage level shifter circuits of claim 1, and transmit the level shifted output signal and the complement the level shifted output signal.

21. The integrated circuit of claim 20, wherein the transmission of the level shifted output signals and the complement the level shifted output signals from the dynamic voltage level shifter circuits are controlled by a clock signal applied to the first and second sets of series-connected transistors of the dynamic voltage level shifter circuits.

22. The integrated circuit of claim 20, further including a memory circuit power domain connected to the output power domain by memory power rails carrying the level shifted the level shifted output signals and the complement the level shifted output signals there-to.

23. The integrated circuit of claim 20, wherein the input power domain includes a logic circuit power domain.

24. The integrated circuit of claim 23, the logic circuit power domain includes one or more logic circuit power rails at the second voltage.
